(19) United States
(12) Patent Application Publication
(10) Pub. No.: US 2026/0173807 A1
(43) Pub. Date: Jun. 18, 2026

(54) ELECTROSTATIC CHUCK

(71) Applicant: TOTO LTD., Fukuoka (JP)

(72) Inventors: Masafumi IKEGUCHI, Fukuoka (JP); Kouta KOBAYASHI, Fukuoka (JP); Jun SHIRAISHI, Fukuoka (JP)

(21) Appl. No.: 19/407,448

(22) Filed: Dec. 3, 2025

(30) Foreign Application Priority Data
Dec. 18, 2024 (JP) 2024-221316

(51) Int. Cl. H01L 21/683; H01J 37/32

(52) U.S. Cl. CPC H10P 72/722; H01J 37/32715; H01J 2237/2007

(57) ABSTRACT

An electrostatic chuck includes a dielectric substrate, a base plate, and a joining layer joining the dielectric substrate with the base plate. The joining layer includes a first joining layer. A second joining layer surrounds the first joining layer in an annular shape on an outer peripheral side. A thermal conductivity of the second joining layer is higher than a thermal conductivity of the first joining layer. With a gas hole formed on an outermost peripheral side among a plurality of gas holes, an end part on an outer peripheral side of the first joining layer is located at a position on an inner peripheral side with respect to a center of the outermost peripheral gas hole. An end part on the inner peripheral side of the second joining layer is located on the outer peripheral side with respect to the center of the outermost peripheral gas hole.

### CROSS-REFERENCE TO RELATED APPLICATION

This application is based upon and claims the benefit of priority from Japanese Patent Application No. 2024-221316 filed on Dec. 18, 2024, the entire contents of which are incorporated herein by reference.

### Field

The present invention relates to an electrostatic chuck.

### Background

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate, and has a configuration in which these are joined to each other. When a voltage is applied to the attraction electrode, an electrostatic force is generated, and the wafer placed on the dielectric substrate is attracted and held.

As disclosed in Japanese Patent Laid-Open No. 2020-23088, the dielectric substrate and the base plate are joined to each other via a joining layer such as a cured silicone adhesive, for example.

### SUMMARY

During processing, fluctuation in an in-plane temperature distribution of the wafer is required to be reduced as much as possible. As a measure for reducing fluctuation in the in-plane temperature distribution, the present inventors have examined making a material of the joining layer different for each position.

The present invention has been made in view of such an issue and is aimed to provide an electrostatic chuck in which fluctuation in an in-plane temperature distribution of a wafer can be reduced.

To address the above-mentioned issue, the electrostatic chuck according to the present invention includes: a dielectric substrate including a placement surface on which an object to be processed is placed, and having a plurality of gas holes formed therein; a base plate supporting the dielectric substrate; and a joining layer joining the dielectric substrate with the base plate. The joining layer includes a first joining layer, and a second joining layer surrounding the first joining layer in an annular shape on an outer peripheral side. A thermal conductivity of the second joining layer is higher than a thermal conductivity of the first joining layer. When the electrostatic chuck is viewed from a direction perpendicular to the placement surface, with a gas hole formed at a position on the outermost peripheral side, among the plurality of gas holes formed on the placement surface on an inner peripheral side with respect to an end part on an outer peripheral side, being defined as an outermost peripheral gas hole, an end part of the first joining layer on the outer peripheral side is positioned on the inner peripheral side with respect to a center of the outermost peripheral gas hole, and an end part of the second joining layer on the inner peripheral side is positioned on the outer peripheral side with respect to the center of the outermost peripheral gas hole.

During processing on the wafer, a temperature of an outer peripheral side part is likely to increase as compared with an inner peripheral side part of the wafer. However, depending on a configuration of the electrostatic chuck, in a part right above the outermost peripheral gas hole, the temperature of the wafer is likely to locally decrease in some cases.

In the electrostatic chuck having the above configuration, a part of the dielectric substrate in the vicinity of the outermost peripheral gas hole is not joined to the base plate by either the first joining layer or the second joining layer. Since the part is less likely to be cooled by the base plate, it is possible to suppress a local temperature decrease at a part right above the outermost peripheral gas hole, and to reduce fluctuation in an in-plane temperature distribution of the wafer.

According to the present invention, it is possible to provide an electrostatic chuck which can reduce fluctuation in the in-plane temperature distribution of the wafer.

### BRIEF DESCRIPTION OF THE DRAWINGS

FIG. 1 is a cross sectional view schematically illustrating a configuration of an electrostatic chuck according to a first embodiment;

FIG. 2 is a diagram illustrating a configuration of a dielectric substrate included in the electrostatic chuck in FIG. 1;

FIG. 3 is a diagram illustrating a configuration of a joining layer included in the electrostatic chuck in FIG. 1;

FIG. 4 is a diagram for explaining a positional relation between a joining layer and a gas hole;

FIG. 5 is a diagram for explaining a positional relation between the joining layer and the gas hole; and

FIG. 6 is a cross sectional view schematically illustrating a configuration of an electrostatic chuck according to a second embodiment.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to attract and hold a wafer W set as a process target by an electrostatic force inside a semiconductor manufacturing apparatus such as, for example, an etching apparatus which is not illustrated in the drawing. The wafer W corresponds to an “object to be processed”, and is a silicon wafer, for example. The electrostatic chuck 10 may be used in an apparatus other than the semiconductor manufacturing apparatus.

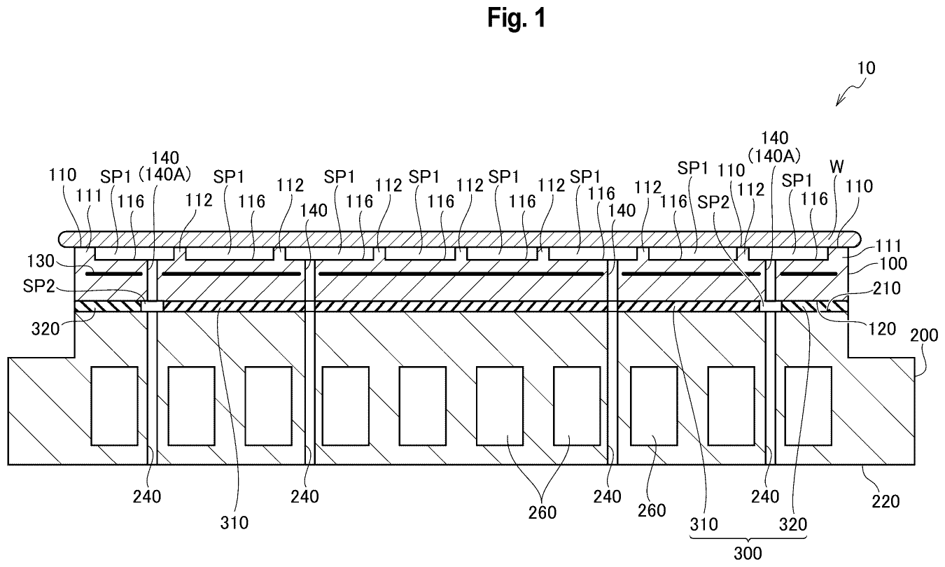

FIG. 1 is a cross sectional view schematically illustrating a configuration of the electrostatic chuck 10 in a state in which the wafer W is attracted and held. The electrostatic chuck 10 includes a dielectric substrate 100, a base plate 200, and a joining layer 300.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300 which will be described later. A perspective in a case where the electrostatic chuck 10 is viewed from the surface 110 side along a direction perpendicular to the surface 110 will also be hereinafter expressed as “top view”.

An attraction electrode 130 is embedded inside the dielectric substrate 100. The attraction electrode 130 is a thin planar layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is attracted and held. The single attraction electrode 130 may be provided as so-called a “monopolar” electrode as in the present embodiment, but may also include two attraction electrodes as so-called “bipolar” electrodes.

As illustrated in FIG. 1, a space SP1 is formed between the dielectric substrate 100 and the wafer W. When a process such as etching is performed in the semiconductor manufacturing apparatus, an inert gas for temperature regulation is supplied to the space SP1 from the outside via a gas hole 140 or the like described later. When the inert gas is caused to be present between the dielectric substrate 100 and the wafer W, a thermal resistance between the dielectric substrate 100 and the wafer W is regulated, and according to this, a temperature of the wafer W is maintained at an appropriate temperature. As the inert gas for temperature regulation to be supplied to the space SP1, a helium gas is used in the present embodiment, but the inert gas may be a gas of a type different from the helium gas.

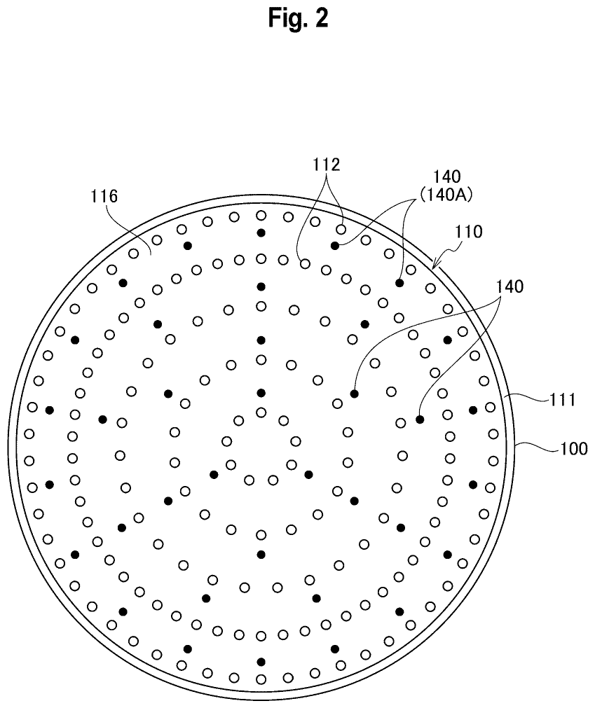

FIG. 2 is a diagram illustrating the dielectric substrate 100 in top view. As illustrated in FIG. 2, a seal ring 111 and a dot 112 are provided on the surface 110 which is the placement surface, and the space SP1 described above is formed around them.

The seal ring 111 is an annular protrusion provided as a wall defining the space SP1 at a position corresponding to the outermost circumference. An upper end of the seal ring 111 becomes a part of the surface 110 and abuts against the wafer W. It is noted that the seal ring 111 may include a plurality of seal rings 111 provided so as to divide the space SP1. With such a configuration, a pressure of the helium gas in each of the spaces SP1 can be individually regulated, and a surface temperature distribution of the wafer W during the process can be set to be close to uniformity.

A part denoted by reference sign “116” in FIG. 1 and FIG. 2 is a bottom of the space SP1. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. As illustrated in FIG. 2, the dot 112 includes a plurality of dots 112 to be provided. The plurality of dots 112 are substantially uniformly distributed and arranged on the placement surface of the dielectric substrate 100. An upper end surface of each of the dots 112 becomes a part of the surface 110 and abuts against the wafer W. By providing the plurality of thus configured dots 112, warping of the wafer W is reduced.

The gas hole 140 is formed in the dielectric substrate 100. The gas hole 140 is a through hole formed so as to extend in a direction perpendicular to the surface 110 serving as the placement surface. An end part on the surface 110 side of the gas hole 140 is connected to the space SP1. The gas hole 140 is a part of a flow path for supplying a helium gas toward the space SP1.

The gas hole 140 includes a plurality of gas holes 140 that are distributed and arranged so as to supply the helium gas to each part of the space SP1. Arrangement of the gas holes 140 in an actual configuration is illustrated in FIG. 2, but FIG. 1 schematically illustrates only four of the gas holes 140.

Among the plurality of gas holes 140, the gas hole 140 formed at a position on the outermost peripheral side in top view is hereinafter also referred to as an “outermost peripheral gas hole 140A”. The outermost peripheral gas hole 140A can also be expressed as the gas hole 140 arranged at a position closest to an outer peripheral side end part of the surface 110 serving as the placement surface from an inner peripheral side. As illustrated in FIG. 2, in the present embodiment, the outermost peripheral gas hole 140A includes a plurality of outermost peripheral gas holes 140A arranged in a circular shape along the seal ring 111.

The base plate 200 is a substantially disk-shaped member which supports the dielectric substrate 100. The base plate 200 is made of, for example, a metallic material such as aluminum. A surface 210 on the upper side in FIG. 1 in the base plate 200 serves as a “surface to be joined” which is joined to the dielectric substrate 100 via the joining layer 300.

A coolant flow path 260 through which a coolant flows is formed inside the base plate 200. When the process such as etching is performed in the semiconductor manufacturing apparatus, the coolant is supplied from the outside to the coolant flow path 260, and according to this, the base plate 200 is cooled down. Heat generated in the wafer W during the process is transferred to the coolant via the helium gas in the space SP1, the dielectric substrate 100, and the base plate 200, and the heat is exhausted to the outside together with the coolant. The supply and exhaustion of the coolant to and from the coolant flow path 260 are performed via openings which are not illustrated in the drawing and which are formed in a surface 220 opposite to the surface 210 in the base plate 200.

Gas holes 240 are formed in the base plate 200. The gas hole 240 is a through hole formed so as to extend perpendicularly from the surface 210 toward the surface 220 side on the opposite side thereof. The gas hole 240 is formed at each position overlapping the gas hole 140 of the dielectric substrate 100 in top view, and communicates with the gas hole 140 via a through hole and the like provided in the joining layer 300. The gas hole 240 serves as a part of the flow path for supplying the helium gas toward the space SP1 together with the gas hole 140 of the dielectric substrate 100.

The gas hole 240 may be formed so as to extend entirely in a linear shape as in the present embodiment, or may be formed so as to bend on a way from the surface 210 toward the surface 220. The plurality of gas holes 240 on the surface 210 side may be aggregated into a small number of flow paths inside the base plate 200, and the flow paths may be extended to the surface 220 side.

An insulating film may be formed on a surface of the base plate 200. The insulating film may be formed so as to cover only a part of a surface of the base plate 200, instead of the entire surface thereof. For example, the insulating film may be formed so as to cover only a side surface part excluding the surface 210 and the surface 220, that is, an exposed part exposed to plasma or the like inside the semiconductor manufacturing apparatus. Alternatively, the insulating film may be formed so as to cover a range including at least the entire surface 210. As the insulating film, for example, an alumina film formed by thermal spraying can be used. When the surface of the base plate 200 is covered by the insulating film, it is possible to increase dielectric withstand voltage of the base plate 200.

The joining layer 300 is a layer provided between the dielectric substrate 100 and the base plate 200 to join those components. The joining layer 300 is obtained by causing an adhesive made of an insulating material to be cured. In the present embodiment, a silicone adhesive is used as the above-mentioned adhesive. It is noted however that the joining layer 300 may be obtained by causing an adhesive of other types to be cured. In any case, in order that a thermal resistance between the dielectric substrate 100 and the base plate 200 is reduced, a material with a highest possible thermal conductivity is preferably used as the material of the joining layer 300.

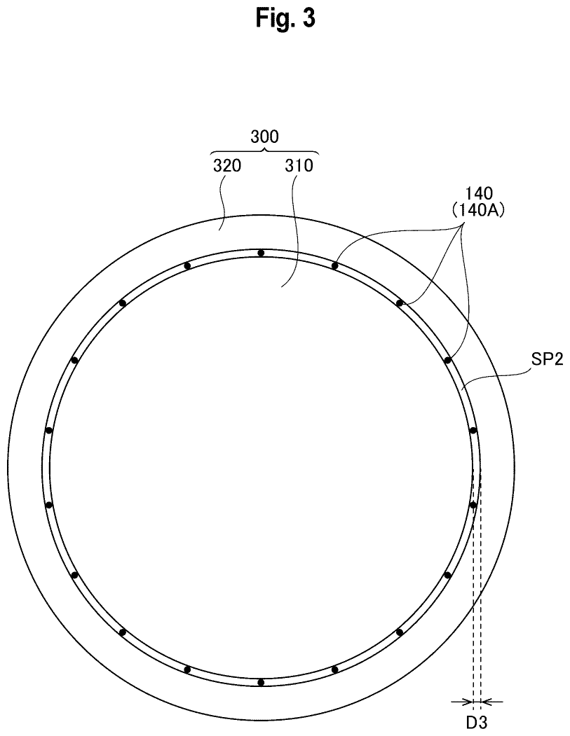

FIG. 3 schematically illustrates a configuration of the joining layer 300 in top view. The through holes are formed at respective parts of the joining layer 300 overlapping the gas holes 140, overlapping a lift pin hole (not illustrated), and the like, but the through holes are not illustrated in FIG. 3. FIG. 3 also illustrates an arrangement of the outermost peripheral gas hole 140A provided in the dielectric substrate 100.

The joining layer 300 of the present embodiment includes a first joining layer 310 and a second joining layer 320. A shape of the first joining layer 310 in top view is a circular shape. In top view, a center of the first joining layer 310 matches the center of the dielectric substrate 100. The second joining layer 320 surrounds the first joining layer 310 in an annular shape on the outer peripheral side. An end part on the outer peripheral side of the first joining layer 310, an end part on the inner peripheral side of the second joining layer 320, and an end part on the outer peripheral side of the second joining layer 320 each have a circular shape in top view, and they are arranged concentrically.

A material of the first joining layer 310 and a material of the second joining layer 320 are different from each other. Specifically, the materials are selected so that a thermal conductivity of the second joining layer 320 is higher than a thermal conductivity of the first joining layer 310. Such a difference in thermal conductivity is achieved, for example, by making amounts of fillers to be put into the adhesive different from each other before the silicone adhesive to be the joining layer 300 is cured.

As schematically illustrated in FIG. 3, in the present embodiment, all of the outermost peripheral gas holes 140A provided in the dielectric substrate 100 are arranged at positions between the first joining layer 310 and the second joining layer 320 in top view, and are arranged side by side at regular intervals along a circumferential direction.

A space SP2 is formed between the first joining layer 310 and the second joining layer 320. As described above, the end part on the outer peripheral side of the first joining layer 310 and the end part on the inner peripheral side of the second joining layer 320 are arranged in a concentric manner in top view. The space SP2 is an annular space formed between both end parts.

As illustrated in FIG. 1 and FIG. 3, the space SP2 is connected to a lower end part of each of the outermost peripheral gas holes 140A. In the present embodiment, all of the plurality of outermost peripheral gas holes 140A are connected to the one space SP2. The helium gas supplied to the gas hole 240 is supplied to the space SP1 via the space SP2 and the outermost peripheral gas holes 140A. That is, the space SP2 serves as a part of the flow path for supplying the helium gas toward the space SP1 together with the gas hole 240 and the gas hole 140.

The number of gas holes 240 provided at positions right below the outermost peripheral gas holes 140A of the base plate 200 may be made smaller than the number of the outermost peripheral gas holes 140A. In such a configuration, the helium gas supplied to the gas hole 240 is distributed to the respective outermost peripheral gas holes 140A while flowing through the space SP2, and is supplied to the space SP1. That is, the space SP2 can also be used as a distribution flow path for distributing the helium gas to the plurality of gas holes 140.

When processing is performed on the wafer W in the semiconductor manufacturing apparatus, it is preferable that fluctuation in an in-plane temperature distribution of the wafer W is as small as possible. However, during the process, a temperature of the wafer W tends to locally increase at a part on the outer peripheral side. Thus, in the present embodiment, as described above, the thermal conductivity of the second joining layer 320 arranged on the outer peripheral side is made higher than the thermal conductivity of the first joining layer 310 arranged on the inner peripheral side. Since the outer peripheral side part of the dielectric substrate 100 (that is, a part supporting the outer peripheral side of the wafer W) is more likely to be cooled by the base plate 200, it is possible to suppress a local temperature increase on the outer peripheral side of the wafer W.

In the present embodiment, to further reduce fluctuation in the in-plane temperature distribution of the wafer W, a relative positional relation between the joining layer 300 and the outermost peripheral gas hole 140A is also devised.

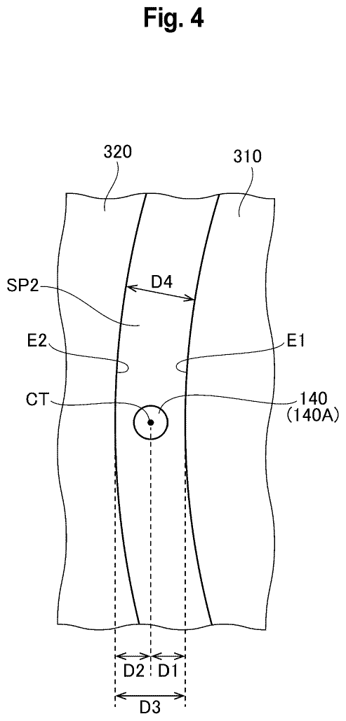

FIG. 4 schematically illustrates the outermost peripheral gas hole 140A and a configuration in a vicinity thereof in top view. In FIG. 4, a curve denoted by reference sign “E1” is a line representing the end part on the outer peripheral side of the first joining layer 310. This end part will also be hereinafter referred to as an “end part E1”. A curve denoted by reference sign “E2” is a line representing the end part on the inner peripheral side of the second joining layer 320. This end part will also be hereinafter referred to as an “end part E2”.

In FIG. 4, a point denoted by reference sign CT represents a position of a center of the outermost peripheral gas hole 140A. The “position of the center of the outermost peripheral gas hole 140A” means a position of a center axis of the outermost peripheral gas hole 140A in top view. This center will also be hereinafter referred to as a “center CT”.

In the present embodiment, shapes and the like of the first joining layer 310 and the second joining layer 320 are set such that the end part E1 on the outer peripheral side of the first joining layer 310 is located at a position on the inner peripheral side with respect to the center CT of the outermost peripheral gas hole 140A in top view, and the end part E2 on the inner peripheral side of the second joining layer 320 is located at a position on the outer peripheral side with respect to the center CT of the outermost peripheral gas hole 140A in top view.

The reason therefor is as follows. As described above, during processing on the wafer W, the temperature of the outer peripheral side part is likely to increase as compared with the inner peripheral side part of the wafer W. However, depending on a configuration of the electrostatic chuck 10, in a part right above the outermost peripheral gas hole 140A, the temperature of the wafer W is likely to locally decrease in some cases. For example, in a case where another seal ring is provided at a position on the inner peripheral side with respect to the seal ring 111 of the dielectric substrate 100, and the outermost peripheral gas hole 140A is provided in the vicinity of the seal ring, a temperature of a part right above the outermost peripheral gas hole 140A may locally decrease.

Thus, in the electrostatic chuck 10 according to the present embodiment, as described above, the end part E1 on the outer peripheral side of the first joining layer 310 is arranged at a position on the inner peripheral side with respect to centers CT of all of the outermost peripheral gas holes 140A, and the end part E2 on the inner peripheral side of the second joining layer 320 is arranged at a position on the outer peripheral side with respect to the centers CT of all of the outermost peripheral gas holes 140A.

In such a configuration, the part of the dielectric substrate 100 in the vicinity of the outermost peripheral gas hole 140A is not joined to the base plate 200 by either the first joining layer 310 or the second joining layer 320. Since the part is less likely to be cooled by the base plate 200, it is possible to suppress a local temperature decrease right above the outermost peripheral gas hole 140A, and to reduce fluctuation in the in-plane temperature distribution of the wafer W.

The positional relation between the first joining layer 310 and the outermost peripheral gas hole 140A, and the positional relation between the second joining layer 320 and the outermost peripheral gas hole 140A, as described above, only need to be established at least in a cross section including both a center axis of the dielectric substrate 100 and a center axis of the outermost peripheral gas hole 140A (that is, a cross section as in FIG. 1). That is, the “end part E1” and the “end part E2” refer to end parts in the above-mentioned cross section. The position of the end part E1 and the position of the end part E2 and the like in a cross section not including the center axis of the outermost peripheral gas hole 140A are not particularly limited.

In top view, a distance from the end part E1 on the outer peripheral side of the first joining layer 310 to the center CT of the outermost peripheral gas hole 140A is hereinafter also referred to as a “distance D1”. A distance from the end part E2 on the inner peripheral side of the second joining layer 320 to the center CT of the outermost peripheral gas hole 140A is hereinafter also referred to as a “distance D2”. When any of the distances D1 and D2 is too large, a temperature decrease at a part right above the outermost peripheral gas hole 140A cannot be sufficiently suppressed. According to experiments and the like conducted by the present inventors, it has been confirmed that, if the distance D1 falls within a range of 2 mm or less and the distance D2 also falls within a range of 2 mm or less, fluctuation in the in-plane temperature distribution of the wafer W can be sufficiently reduced.

In the present embodiment, the end part E1 on the outer peripheral side of the first joining layer 310 and the end part E2 on the inner peripheral side of the second joining layer 320 are separated from each other over the entire circumference, and the space SP2 is formed therebetween. With such a configuration, when the dielectric substrate 100 and the base plate 200 are joined, the first joining layer 310 and the second joining layer 320, which are different kinds of adhesives, are prevented from being mixed, thereby preventing a situation in which their respective physical properties are changed. In a case where a change in the physical property of the adhesive due to solid diffusion and the like is not a problem, a joining layer made of another material may be present between the first joining layer 310 and the second joining layer 320. In this case, as a material of the joining layer, it is preferable to use a material having a lower thermal conductivity than that of either the first joining layer 310 or the second joining layer 320.

In top view, a distance from the end part E1 on the outer peripheral side of the first joining layer 310 to the end part E2 on the inner peripheral side of the second joining layer 320 is hereinafter also referred to as an “interlayer distance”. Such an interlayer distance is defined not only in a part where the first joining layer 310 and the second joining layer 320 sandwich the outermost peripheral gas hole 140A but also in a part where they do not sandwich the outermost peripheral gas hole 140A. In FIG. 3, reference sign “D3” denotes an interlayer distance in a part where the first joining layer 310 and the second joining layer 320 are adjacent to each other while sandwiching the outermost peripheral gas hole 140A therebetween. In FIG. 3, reference sign “D4” denotes an interlayer distance in a part where the first joining layer 310 and the second joining layer 320 are adjacent to each other without sandwiching the outermost peripheral gas hole 140A therebetween.

In the present embodiment, in the entire part where the first joining layer 310 and the second joining layer 320 are adjacent to each other without sandwiching the outermost peripheral gas hole 140A, the interlayer distance (D4) falls within a range of 2 mm or less. With such a configuration, it is possible to prevent a situation in which the temperature of the wafer W locally and excessively increases in a part right above a part between the first joining layer 310 and the second joining layer 320.

Furthermore, in the present embodiment, including the part where the first joining layer 310 and the second joining layer 320 are adjacent to each other while sandwiching the outermost peripheral gas hole 140A, the above interlayer distance is constant irrespective of a position in the circumferential direction (that is, over the entire circumference). With such a configuration, fluctuation in the in-plane temperature distribution of the wafer W in the circumferential direction can be reduced.

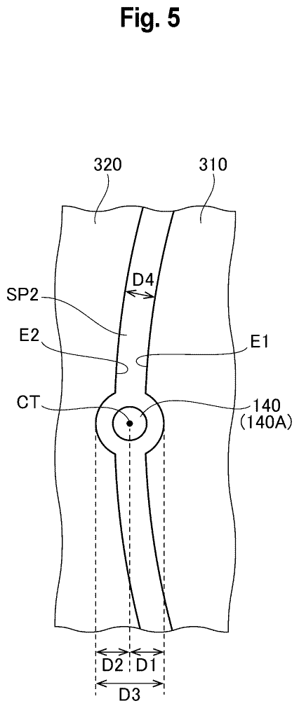

FIG. 5 schematically illustrates a configuration of the electrostatic chuck 10 according to a modification of the present embodiment in the same manner as in FIG. 4. In this modification, the first joining layer 310 and the second joining layer 320 are arranged so as to avoid a circular range surrounding the outermost peripheral gas hole 140A in top view. As a result, the interlayer distance (D3) in the part where the first joining layer 310 and the second joining layer 320 are adjacent to each other while sandwiching the outermost peripheral gas hole 140A therebetween is larger than the interlayer distance (D4) in the part where the first joining layer 310 and the second joining layer 320 are adjacent to each other without sandwiching the outermost peripheral gas hole 140A therebetween. In such a configuration, while D4 may fall within a range of 2 mm, D3 may exceed 2 mm.

The interlayer distance may fall within a range of 2 mm or less as described above only in the part where the first joining layer 310 and the second joining layer 320 are adjacent to each other without sandwiching the outermost peripheral gas hole 140A therebetween. Similarly, the above interlayer distance may be constant only in the part where the first joining layer 310 and the second joining layer 320 are adjacent to each other without sandwiching the outermost peripheral gas hole 140A therebetween. However, in any case, it is preferable to keep each of the distances D1 and D2 within a range of 2 mm or less.

In a case where a change in the physical property of the adhesive due to solid diffusion and the like is not a problem, the interlayer distance (D3) in the part where the first joining layer 310 and the second joining layer 320 are adjacent to each other without sandwiching the outermost peripheral gas hole 140A therebetween may be set to 0 mm. That is, the above range of “2 mm or less” also includes 0 mm.

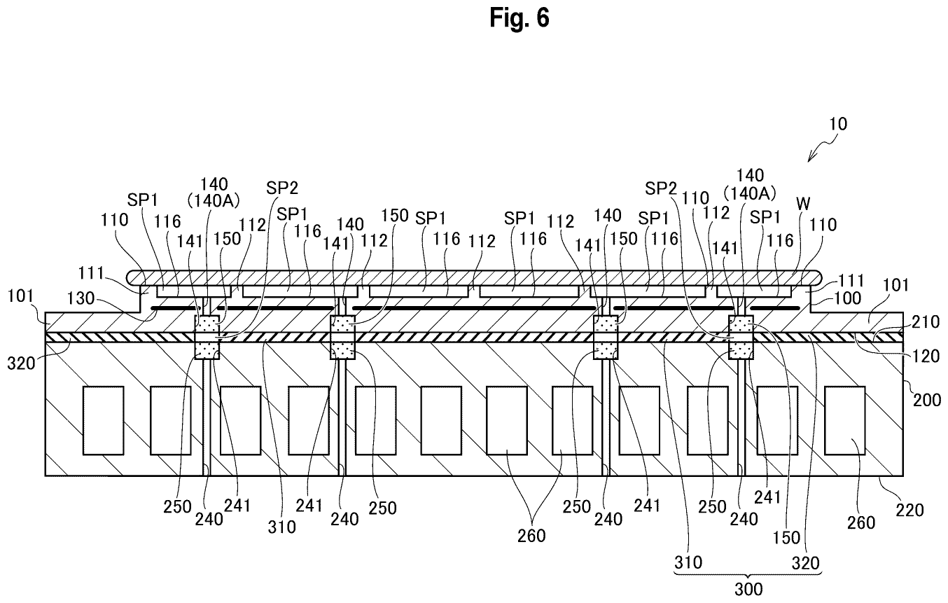

A second embodiment will be described with reference to FIG. 6. In the following, features different from those of the first embodiment will be mainly described, and description of features common to those of the first embodiment is omitted as appropriate.

The dielectric substrate 100 of the present embodiment is provided with a rim portion 101. The rim portion 101 is a part protruding further towards the outer peripheral side relative to the surface 110 serving as the placement surface. In top view, the rim portion 101 surrounds the entire surface 110 from an outer side. A surface on the wafer W side (a surface on an upper side in FIG. 6) of the rim portion 101 is located at a position on the base plate 200 side (a lower side in FIG. 6) relative to the surface 110. When the wafer W is processed, an annular member referred to as a “focus ring” or the like which is not illustrated in the drawing is placed on the rim portion 101.

A gas hole may be formed in the rim portion 101 so that the helium gas can be supplied to a part right below the annular member. Such a gas hole is provided at a position further on the outer peripheral side than the outermost peripheral gas hole 140A in the first embodiment. However, the “outermost peripheral gas hole” is defined as the gas hole 140 formed at a position on the outermost peripheral side among the plurality of gas holes 140 formed on the inner peripheral side with respect to the end part on the outer peripheral side of the placement surface (surface 110) on which an object to be processed (the wafer W) is placed. Thus, even when a gas hole is also formed in the rim portion 101, this gas hole does not correspond to the “outermost peripheral gas hole”.

As illustrated in FIG. 6, a part on the surface 120 side of the gas hole 140 of the present embodiment has an expanded diameter as compared with a part on the surface 110 side. The part having such an expanded diameter is also referred to as an “expanded-diameter part 141” hereinafter. An air-permeable plug 150 is arranged inside the expanded-diameter part 141. The air-permeable plug 150 is a porous body formed of, for example, alumina, and the entire plug is air-permeable. By arranging the air-permeable plug 150 as described above inside the gas hole 140, while a flow of the gas in the gas hole 140 is secured, occurrence of dielectric breakdown in a path through the gas hole 140 can be suppressed. Note that the part of the air-permeable plug 150 having air-permeability may be only a part of the air-permeable plug 150, instead of the entire plug. For example, only a part on a center side of the air-permeable plug 150 may have air-permeability, and a part on the outer peripheral side need not necessarily have air-permeability.

As illustrated in FIG. 6, a part on the surface 210 side of the gas hole 240 of the present embodiment has an expanded diameter as compared with a part on the surface 220 side. The part having such an expanded diameter is also referred to as an “expanded-diameter part 241” hereinafter. An air-permeable plug 250 is arranged inside the expanded-diameter part 241. The air-permeable plug 250 is a porous body formed of, for example, alumina, and the entire plug is air-permeable. By arranging the air-permeable plug 250 as described above inside the gas hole 240, while a flow of the gas in the gas hole 240 is secured, occurrence of dielectric breakdown in a path through the gas hole 240 can be suppressed. Note that the part of the air-permeable plug 250 having air-permeability may be only a part of the air-permeable plug 250, instead of the entire plug. For example, only a part on a center side of the air-permeable plug 250 may have air-permeability, and a part on the outer peripheral side need not necessarily have air-permeability.

With the configuration as described above, an effect similar to that described in the first embodiment can also be attained.

Also in the configuration in which the dielectric substrate 100 is provided with the rim portion 101 as in the present embodiment, the second joining layer 320 is preferably provided at a position where a part thereof overlaps with the placement surface (surface 110) in top view.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate including a placement surface on which an object to be processed is placed and having a plurality of gas holes formed therein;
a base plate supporting the dielectric substrate; and
a joining layer joining the dielectric substrate with the base plate, wherein the joining layer includes a first joining layer, and a second joining layer surrounding the first joining layer in an annular shape on an outer peripheral side,
a thermal conductivity of the second joining layer is higher than a thermal conductivity of the first joining layer, and
when viewed from a direction perpendicular to the placement surface,
with the gas hole formed at a position on an outermost peripheral side, among the plurality of gas holes formed on an inner peripheral side with respect to an end part on an outer peripheral side of the placement surface, being defined as an outermost peripheral gas hole,
an end part on the outer peripheral side of the first joining layer is located at a position on the inner peripheral side with respect to a center of the outermost peripheral gas hole, and
an end part on the inner peripheral side of the second joining layer is located at a position on the outer peripheral side with respect to the center of the outermost peripheral gas hole.

2. The electrostatic chuck according to claim 1, wherein the first joining layer is separated from the second joining layer over the entire circumference.

3. The electrostatic chuck according to claim 2, wherein a space is formed between the first joining layer and the second joining layer, and the space is connected to the plurality of gas holes.

4. The electrostatic chuck according to claim 1, wherein
when viewed from the direction perpendicular to the placement surface,
a distance from the end part on the outer peripheral side of the first joining layer to the center of the outermost peripheral gas hole is 2 mm or less, and
a distance from the end part on the inner peripheral side of the second joining layer to the center of the outermost peripheral gas hole is 2 mm or less.

5. The electrostatic chuck according to claim 1, wherein
when viewed from the direction perpendicular to the placement surface,
in a part where the first joining layer and the second joining layer are adjacent to each other without sandwiching the gas hole therebetween,
a distance from the end part on the outer peripheral side of the first joining layer to the end part on the inner peripheral side of the second joining layer is 2 mm or less.

6. The electrostatic chuck according to claim 5, wherein
when viewed from the direction perpendicular to the placement surface,
in the part where the first joining layer and the second joining layer are adjacent to each other without sandwiching the gas hole therebetween,
a distance from the end part on the outer peripheral side of the first joining layer to the end part on the inner peripheral side of the second joining layer is constant irrespective of a position in a circumferential direction.
